(19) United States
(12) Patent Application Publication
(10) Pub. No.: US 2011/0100429 A1
(43) Pub. Date: May 5, 2011

(54) SOLAR ENERGY ASSEMBLIES

(76) Inventor: Humayun Akhter Mughal, Essex (GB)

(21) Appl. No.: 12/997,361

(22) PCT Filed: Jun. 11, 2009
(86) PCT No.: PCT/GB09/50660

§ 371 Date: Dec. 10, 2010

(30) Foreign Application Priority Data
Jun. 11, 2008 (GB) 0810683.3
Jun. 11, 2008 (GB) 0810684.1
Jun. 11, 2008 (GB) 0810685.8
Jun. 11, 2008 (GB) 0810686.6
Jun. 11, 2008 (GB) 0810687.4
Jun. 11, 2008 (GB) 0810689.0
Jun. 11, 2008 (GB) 0810690.8

(51) Int. Cl. H01L 31/052

(52) U.S. Cl. 136/246

(57) ABSTRACT

A solar energy assembly for collecting and converting solar energy. It comprises a plurality of solar energy converters 36 and an equivalent number of solar concentrator lenses 39, each lens being associated with one energy converter 36 and being adapted to concentrate light onto that energy converter. The lenses may be separate from each other and may be mounted and replaced independently of the others. One or more panel 20 may be mounted on a support frame 21,22, each panel having a plurality of solar energy converters and a lens array adapted to focus light on to the solar energy converters. The lens array may have a lens mounting system 37,38,66,58 adapted to hold it the desired focal distance from the solar energy converters.

The present invention relates to solar panels and solar energy assemblies, in particular those formed with lenses that concentrate the light for an area on to a smaller solar energy converter.

The conversion of solar energy to useful forms, such as in the generation of electricity or in the heating of substances is increasingly important due to changes in the availability of other energy sources and the environmental impact of fossil fuel combustion. Whilst the conversion of solar energy into useable forms has been possible for many years the efficiency of this process and its high cost has limited the overall effectiveness of using solar power.

It is an aim of the present invention to overcome these and other such problems and to provide improved designs for the construction of solar panels, solar energy assemblies and components therefor.

According to a first aspect of the present invention there is provided a solar energy assembly comprising a plurality of solar energy converters and an equivalent number of solar concentrator lenses, each lens being associated with one energy converter and being adapted to concentrate light onto that energy converter.

The lenses may be separate from each other and may be mounted and replaced independently of the others. This allows a lens to be individually replaced if it is damaged, which reduces the cost as the entire array is not scrapped. Further, each individual lens is aligned with respect to its own associated converter and is not effected by the position of the other lenses. Misalignment can be a significant problem as the light is not correctly focussed, and in a large array of multiple conjoined lenses a small error in size can be multiplied across a series such that a major misalignment can occur. For example, if each lens is just 1% too big, after the first lens in a row there is only a small misalignment, but after say 20 lenses this will have become at least 20% of the lens size which might be larger than the area of the converter itself, thus a major problem. However, in the present invention such cumulative problems are avoided and the manufacturing tolerances of the lenses can be lower making them cheaper. Preferably the ratio of lenses to energy converters is 1:1.

A lens mounting system may be provided to mount the lenses the correct focal distance above the energy converters. This may take the form of a plurality of supports adapted to support the corners or edges of adjacent lenses.

The solar energy converters may be arrayed in a regular spaced pattern across one or more base plate. Each solar energy converter may be positioned under the centre of each lens.

The solar energy converters are preferably provided on a panel and the lenses are mounted above that panel. The solar energy assembly may comprise: one or more such panel mounted on a support frame, each panel having a plurality of solar energy converters; a lens array adapted to focus light on to the solar energy converters; and a lens mounting system adapted to hold the lens array the desired focal distance from the solar energy converters.

In order that the optimum alignment to the sun is maintained it is preferably that the support frame is pivotally connected to the mounting so that the solar energy converters and associated lens array may track the movement of the sun. A tracking assembly may be provided to move the support frame relative to the mounting, the tracking assembly causing movement about up to two generally perpendicular axes of rotation.

The term solar panel as used herein may describe any device that has solar energy converters and associated components that convert the suns energy into useable forms such as electricity.

The tracking assembly may comprise a crank, a first linear actuator connected to the mounting and the crank and a second linear actuator connected to the crank and the support frame, whereby linear extension of one or both actuators causes pivoting movement of the panel relative to the mounting.

The crank needs to be able to rotate and to couple the linear extension of the first and second actuators. It is possible for the crank to be pivotally connected to the mounting or the support frame; however it is advantageous to have the crank connected to the mounting.

Movement of the first linear actuator may cause rotation of the crank about its connection to the mounting. This causes the second actuator to move, even if it is not extending, which in turn moves the panel to which the second actuator is attached. The first linear actuator may be connected to the crank at a first point and the second linear actuator may be connected to the crank at a second point. Both such points are spaced from each other and are radially spaced from the axis of rotation of the crank. Therefore rotation of the crank causes curved movement of both the loci of the actuator connection points. The crank may take the form of a bell crank.

The tracking assembly of the present invention may be provided with a further actuator to move the panel about a second axis generally at right angles to the first axis. This further actuator may include one or more linear actuator. It may be equivalent to the combination of first actuator, crank and second actuator. Alternatively it may comprise a single linear or alternative actuator.

The first axis is often generally vertical and rotational movement about that axis cause horizontal tracking of the solar panel. Such horizontal tracking must be made through a wide arc (sometimes in the region of 160°) as the sun moves a long way around the horizon during the day. The second axis may be generally horizontal such that rotation thereabout causes vertical tracking of the solar panel.

The mounting may be formed in two relatively moveably parts with an upper portion that is pivotally mounted to a lower portion. The movement of the upper portion with respect to the lower portion can be achieved by the further actuator to effect vertical scanning of the panel. The panel and support frame may be pivotally connected to the upper portion with the first linear actuator, crank and second linear actuator moving the panel with respect to the upper portion. In such an arrangement the crank and first linear actuator are connected to the upper portion.

A plurality of panels may be are attached side by side to form a composite panel. Such panels forming a composite panel are also herein referred to as sub-panels.

Vents may be provided to allow air to pass between the panel and the lens array and/or through the panel. Vents may be provided by one or more of: spaces between adjacent sub-panels, openings in the lens array, and openings in the mounting system.

The fluid may of course be anything that provides the desired cooling function without effecting the operation of the solar panel. In most cases it would be a gas and usually air, as the solar energy assembly is usually mounted outside in the sunlight. The present invention will, for convenience, be described with respect to the flow of air.

The purpose of the venting gaps is to allow air to pass over and between the sub-panels to cool them. The vents can allow the flow of air currents around each sub-panel, so that heat generated during operation will be dissipated by the air.

The panels or sub-panels are preferably formed with a base plate made of thermally conductive materially, for example a metal such as aluminium. Energy converters are attached on one side of this in such a way that if desired (for example if the energy converters are photovoltaic cells) the heat generated may be dissipated to the base plate and then to the air passing thereover.

The frame on which the sub-panels are mounted may permit the flow of fluid through the venting gaps. This frame may be comprised of a grid of vertical and/or horizontal bars to which the sub panels may be connected. Each sub-panel may be a discrete modular unit that may be independently removed from the panel. This allows a broken sub-panel to be replaced without the need to replace all of the other parts of the panel. This makes maintenance and repair of the assembly a realistic possibility.

Venting gaps may be provided between some of the edges of some of the sub-panels. However it is preferred that venting gaps are provided between all adjacent edges of the sub-panels. The venting gaps can easily be formed by leaving spaces between the sub-panels.

Each sub-panel produces an output of energy collected from the sun. These separate outputs may be combined to provide a single output from the panel.

The provision of venting gaps also provides an advantage for the installation of solar panels outside. Solar panels being necessarily large in area are subject to wind force. Up to a point this helps to cool the panel, but they can suffer from damage caused by their resistance to the wind. The provision of the venting gaps reduces their resistance to the wind thereby reducing the potential for damage and the strength of mounting required.

A cleaning system may be provided to clean the panel, sub-panels and/or lens array. Such a cleaning system may direct cleaning fluid into an internal space defined between the upper surfaces of the sub-panels and the inner face of the lens array. The space may also be bounded by walls between the lens array and panel if they are present. This area may be substantially sealed or open, but will usually not be readily accessible for cleaning purposes. Therefore any dirt or debris, such as dust, that collects on those internal surfaces will be hard to remove without disassembling parts such as the lens array. That is neither fast nor desirable so the cleaning system of the present invention provides a mechanism by which the dirt may be cleaned from this space fast, automatically and without disassembly.

The cleaning system delivers a cleaning fluid, be that liquid or gas to the relevant parts. This may be achieved in a number of ways, but preferably it is achieved by a providing a system of nozzles through the cleaning fluid is sprayed. Pipes or conduits linking those nozzles to a source of cleaning fluid may also be provided.

The mounting system may include legs that extend between the panel and the lens array, and the cleaning system may include one or more spray nozzle on said legs. Preferably each leg has multiple nozzles to direct fluid upward onto the lens array and downwards onto the panel. Pipes linking those nozzles to the source of cleaning fluid may be provided on in the legs.

As the outside face of the lens array is also liable to get dirty it is advantageous that the cleaning system is also adapted to direct fluid onto an external face of the lens array. A cap or other extension may be provided on each leg and that cap or extension may have nozzles to direct fluid onto the outer face of the lens array. The cleaning fluid may preferably be water, compressed air or a combination thereof.

The lenses may be any shape, or combination of shapes, but preferably they are polygonal and tessellate. This can form a substantially continuous array, although small gaps may be formed between each lens, maximising the area of sun focussed onto the converters.

The mounting system may comprise a plurality of legs that connect to the panel or sub-panels and the lens array. The legs may be adapted to connect to the corners of adjacent lenses. For example it has been found that generally rectangular lenses are highly suitable as they may be packed into even rows and columns and may focus effectively onto square converters. The legs may be adapted to support four meeting corners of four adjacent rectangular lenses.

A leg may be provided at each corner or group of corners. This will require slightly more legs than lenses, but any suitable arrangement may be employed. For example an array of forty eight square lenses in six rows of eight could be supported by sixty three legs. The legs around the edge of the array would need to support only one or two corners each but those in the middle would support four corners each.

At least partially to enclose the internal space between the panel and the lens array and or to improve strength, side walls may be provided around the periphery of the panel or lens array (if it does not extend to the full area of the panel). These may be connected to any suitable parts but preferably are each connected between a pair of legs nearest the edge of the panel. The side walls may be provided with formation to engage the legs. The side walls may be provided with ventilation holes to permit the flow of air to the internal space.

The legs may attach to the panel by a variety of methods. One currently envisaged and convenient way involves the legs attaching to the panel by twist locking into apertures in the panel. The lower end of each leg may have a key formation that locates through the aperture at one position but locks in place by rotation.

The upper end of each leg may be provided with releasable interlocking means that cooperate with formations on the lenses to hold the lenses in place. This may include a cap that attaches to the upper end of the leg once one or more lens has been positioned thereon. The upper end of each leg may have four recesses, and the corner of each lens may have a tab that locates into one of those recesses. The cap may attach to the upper end of the leg to hold those tabs in those recesses. The cap may also have downwardly projecting formations that engage in slots on the upper surface of the lenses.

The legs might also be interconnected by a framework that defines frame into which the lenses locate.

Each panel may comprise a base sheet formed from a material of high thermal conductivity and a carrier strip having photovoltaic cells spaced therealong. The carrier strip may be bonded to the base sheet so that the base sheet may provide both mechanical support and a heat sink for the photovoltaic cells.

Each base plate may have one or a plurality of strips provided thereacross. If two or more strips are provided on the base sheet they may be substantially parallel to each other. Preferably such strips are arranged generally horizontally in use to minimise shadowing.

Preferably the base sheet is formed from metal, as this provides good mechanical strength and thermal conductive properties to dissipate heat from the photovoltaic cells. The base sheet may advantageously be formed from aluminium.

The present invention can be used with any sort of solar energy converters, but it is preferred that the solar panel is provided with an array of photovoltaic cells

The lens array may comprise a plurality of Fresnel lenses. Such lenses may comprise a plurality of discrete prismatic sub-lenses that are suitably angled each to direct light on to the target area. The desired focal distance of the lens may be within the range of 18 to 22 cm.

According to a second aspect of the present invention there is provided a solar energy assembly for collecting and converting solar energy, comprising: a mounting; a support frame mounted on the mounting; a solar panel formed from a plurality of discrete sub-panels, attached side by side to the support frame, each sub-panel having a plurality of solar energy converters; a lens array adapted to focus light on to the solar energy converters; and a lens mounting system adapted to hold the lens array the desired focal distance from the solar energy converters.

According to a third aspect of the present invention there is provided a solar panel for use with an array of solar concentrator lenses, the panel comprising a base plate formed from a material of high thermal conductivity and a carrier strip having photovoltaic cells spaced therealong, the carrier strip and photovoltaic cells being bonded to the base plate which provides both a mechanical support and a heat sink for the photovoltaic cells.

Each such base plate may have one or a plurality of strips provided thereacross. If two or more carrier strips are provided on the base sheet they may be placed substantially parallel to each other.

The base sheet is preferably formed from a metal or metals, as these provide good mechanical strength and thermal conductive properties to dissipate heat from the photovoltaic cells. The base sheet may advantageously be formed from aluminium as this is also light.

Wiring to link the photovoltaic cells of a carrier strip together may also be provided on the carrier strip. This may also be linked to other strips to provide a unified output from all the cells on a solar panel.

Materials, such as ones which increase the thermal or structural interaction of the carrier strips or cells with the base plate may also be provided between the strip and the base plate.

According to a fourth aspect of the invention there is also provided a method of manufacturing a solar panel of the third aspect, the method comprising forming a base plate from a material of high thermal conductivity; providing a carrier strip comprising a carrier web and photovoltaic cells spaced therealong; and bonding the carrier strip to the base plate so that the base plate provides mechanical support and a heat sink for the photovoltaic cells.

The carrier strip(s) and, if present, the protective cover layer may be co-laminated with the base sheet. The bonding of the carrier strip may be achieved by any suitable means such as adhesives. Such adhesives may preferably provide good thermal coupling to the base plate.

If additional materials are to be provided between the strip and the base plate, these may if appropriate, all be applied to the base plate in a single co-lamination step with the carrier strips.

According to a fifth aspect the present invention there is provided a solar panel formed from a plurality of sub-panels, attached side by side in a spaced array with venting gaps provided between the edges of adjacent sub-panels.

The purpose of the venting gaps and the optional modifications thereof are as described above

According to a sixth aspect of the present invention there is provided a lens mounting system to mount solar concentrator lenses above a panel having an array of solar energy converters, the mounting system comprising a plurality of legs that connect to the panel and to the edges of the lenses.

According to a seventh aspect of the present invention there is provided a solar energy assembly comprising: a panel provided with solar energy converters on an upper surface thereof; a solar concentrator lens array to direct light onto the converters; a mounting system to mount the lens array in spaced arrangement above the upper surface of the panel defining an internal space therebetween; and a cleaning system adapted to direct fluid into the internal space for cleaning the upper surface of the panel and/or an inside face of the lens array.

In order that it may be better understood, but by way of example only, certain embodiments of the present invention will now be described in more details with reference to the accompanying drawings in which:

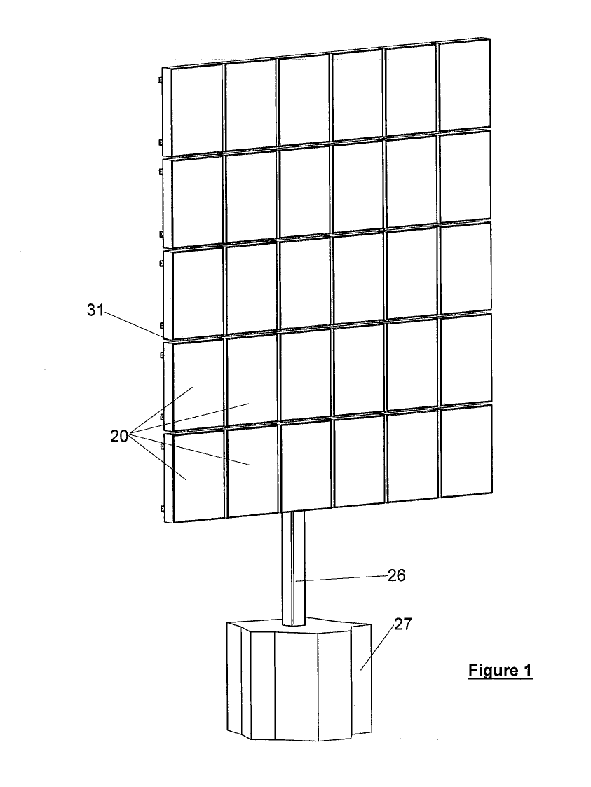

FIG. 1 is a perspective view from the front of a solar energy assembly according to the present invention;

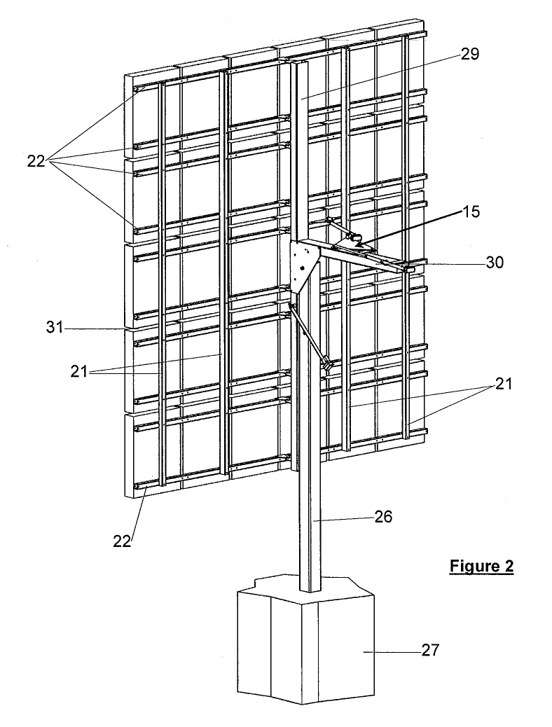

FIG. 2 is a perspective view from behind of the same embodiment;

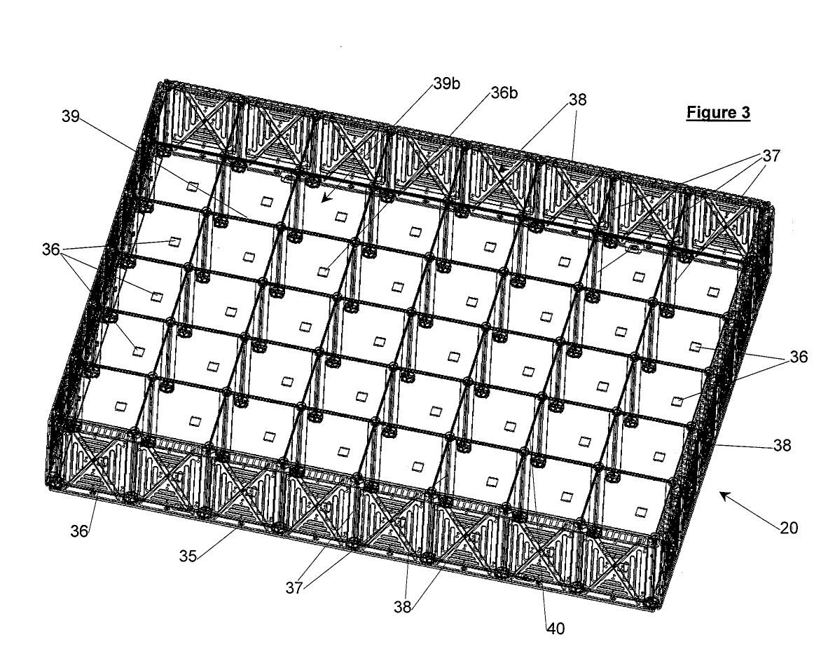

FIG. 3 is an isometric view of a sub-panel;

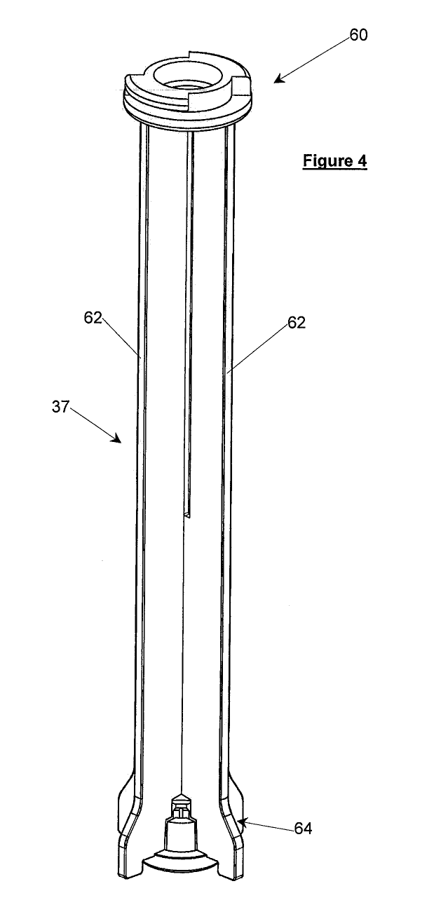

FIG. 4 is a perspective view of a leg of the support system;

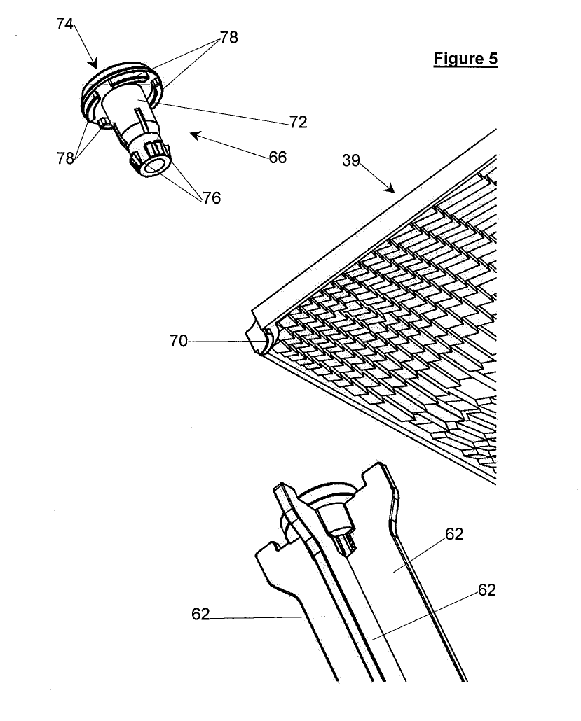

FIG. 5 is an exploded view from below of a lens being connected to a leg;

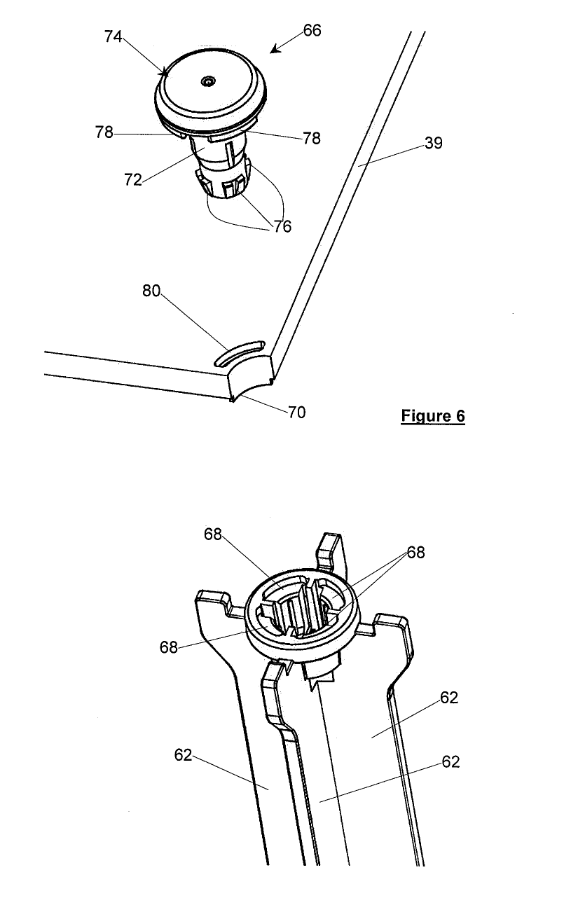

FIG. 6 is an equivalent exploded view from above;

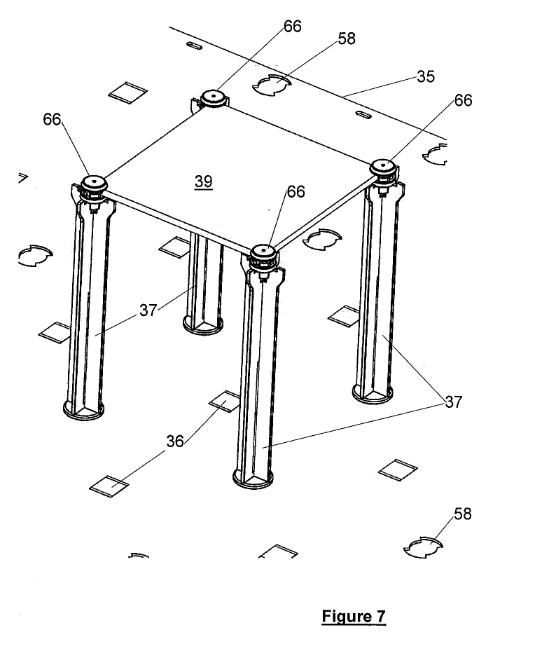

FIG. 7 shows a single lens being supported by four legs;

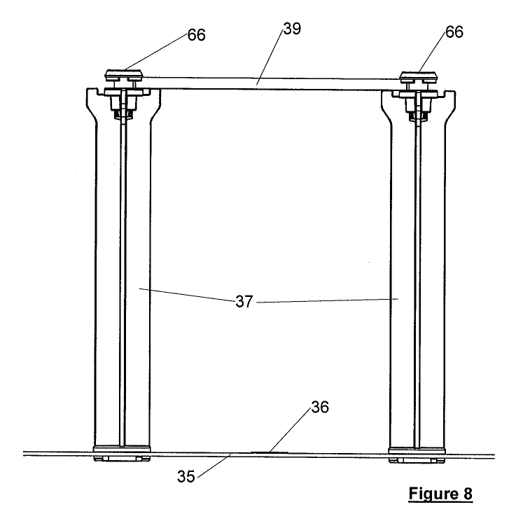

FIG. 8 is an equivalent arrangement but viewed from the side;

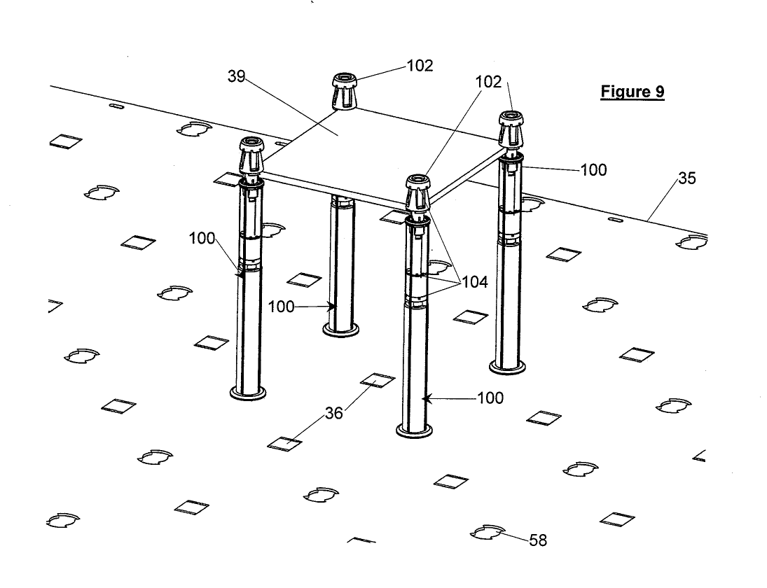

FIG. 9 is equivalent to the view shown in FIG. 7 but the legs are a different embodiment and are provided with an internal cleaning mechanism;

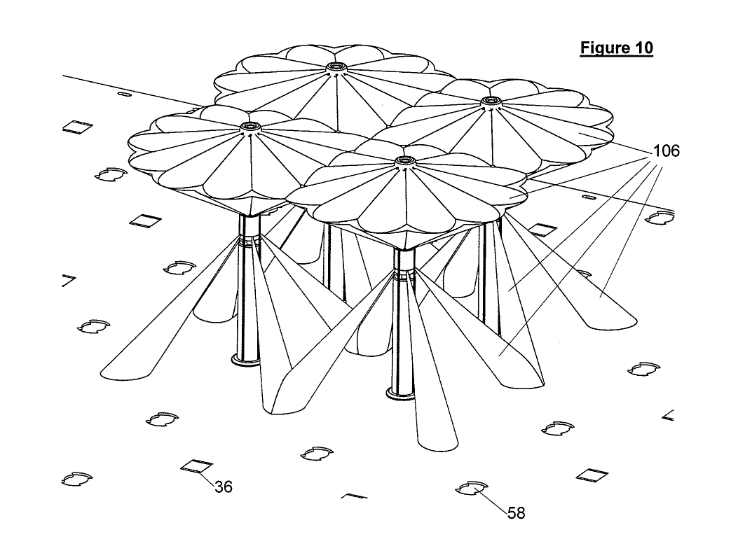

FIG. 10 is the same as FIG. 9 but showing the cleaning spray pattern from said cleaning system;

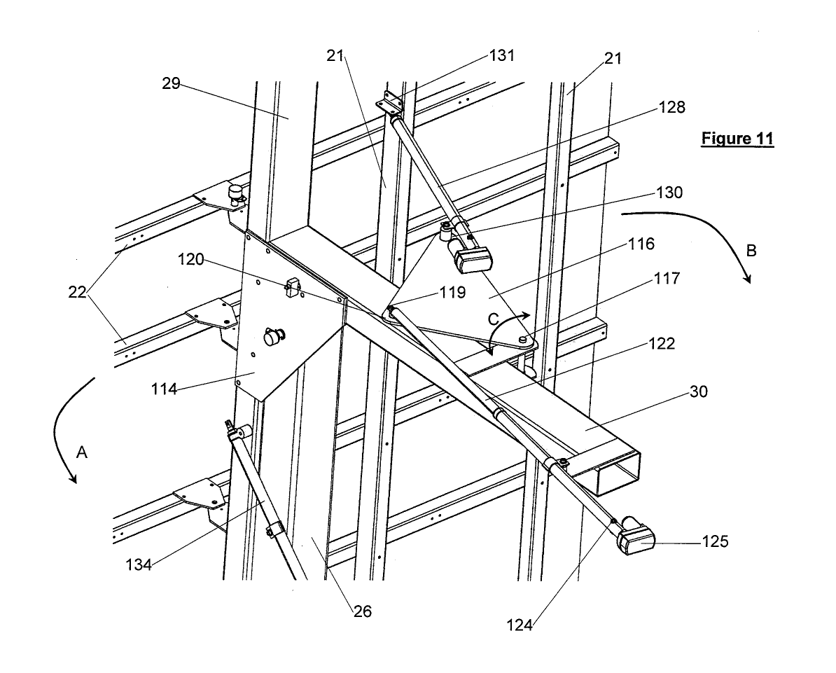

FIG. 11 is an enlargement of the tracking assembly;

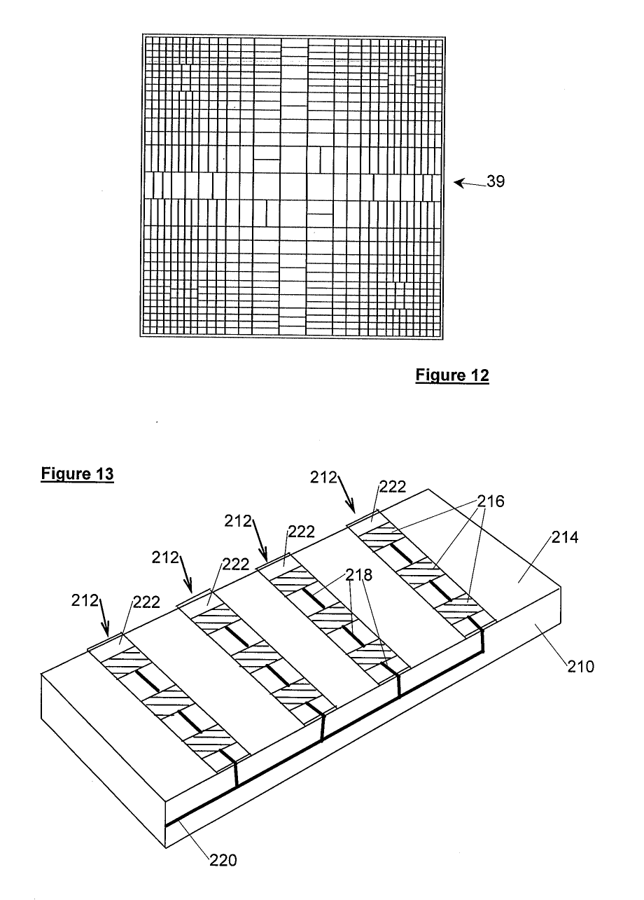

FIG. 12 is a plan view of a lens; and

FIG. 13, which is a simplified representation of a slightly different embodiment panel bearing strips of solar energy converters.

The solar energy assembly of the present invention generally comprises a solar panel formed from an array of thirty sub-panels 20 on a support frame formed from vertical beams 21 and lateral beams 22.

A support pillar 26 is fixed to the ground 27. Pivotally connected to the top of the support pillar 26 is a generally T-shaped sub-frame which comprises a vertical member 29 and a horizontal member 30. The support frame and attached sub-panels are pivotally connected to the vertical member 29 to rotate about a vertical axis. As will be described in more detail later a tracking assembly is provided to control the movement of the panel about these two axes to follow the progress of the sun during the day.

FIGS. 1 and 2 show a solar energy assembly formed from 30 sub-panels 20 which are arranged side-by-side in a 6×5 arrangement with six columns and five rows. Between the adjacent edges of each sub-panel 20, there are formed venting gaps generally indicated 31. These venting gaps extend vertically between each column of sub-panels and horizontally between each row. As the sub-panels are connected at the rear to the lateral supports there is nothing to obstruct the flow of air between the sub-panels.

In FIG. 1 the sub-panels 20 are shown in a simplified form. However, each sub-panel comprises a somewhat more complicated arrangement as depicted in FIG. 3. FIG. 3 shows an isometric view of one embodiment of sub-panel 20. It comprises a base plate 35 to which are attached forty eight solar energy converters in the form of photovoltaic cells 36. The photovoltaic cells 36 are arranged in a regular pattern of 6×8.

A lens mounting system is provided on the base plate 35. This comprises a plurality of legs 37 arranged in a regular pattern of 9×7 giving a total of sixty three legs. Attached between the legs 37 and around the outside of the panel 10 are side walls 38. There are eight side wall panels along each of the long sides and six along each of the short sides giving a total of 28 side wall panels in total. These side wall panels each have a plurality of apertures to permit air or fluid flow therethrough.

Supported by the legs 37 are 48 solar concentrator lenses 39. There is the same amount of solar concentrator lenses 39 as there are photovoltaic cells 36 and each lens focuses light onto one photovoltaic cell 36. Due to the point-of-view in the figure the photovoltaic cell 36 appearing within the area bounded by each lens is in fact not the cell on which the light is concentrated. If viewed from above the correct cell would appear within the correct lens, however in this drawing a lens at position 39b would focus light onto cell 36b.

The corner of each lens 39 is supported on a leg 37 and each lens is supported at each of its four corners. The lenses 39 are all separate and one may be removed simply by disconnecting it from the four associated legs. This allows a particular lens to be replaced or repaired without removal of the other lenses. Further, it allows each lens to be positioned with respect to its cell 36 without problems caused by the misalignment of other cells. The cells are spaced slightly from each other such that gaps 40 are defined between adjacent edges of rows and columns of lenses. These gaps, along with the apertures provided in the side walls and gaps between the sub-panels, help to allow circulation of air through the space defined between the lenses and the base plate 35.

So as not to obscure the panel and cells therebelow, the lenses in FIG. 3 are shown as clear. However, in practice such lenses would by their nature distort the light to concentrate it onto the cells. Preferably such lenses would take the form of square Fresnel lenses, each lens having multi-faceted prismatic sub-lenses. FIG. 12 shows a suitable lens.

FIG. 4 shows a leg 37 in more detail but upside down. The lower end 60 of the leg is provided with a retaining mechanism that is adapted to engage with keyway slots, formed in the base plate, by insertion into said slot and rotation to engage therewith. This allows easy assembly and disassembly as required. The shaft of the leg is defined by four fins 62 arranged at approximately 90° to each other. As can be seen in FIGS. 5 and 6 the upper end 64 of the leg is adapted to engage with the corner regions of the lenses and a cap 66. The fins 62 flare outwardly at the upper end 64 to provide additional support to the lenses. Four depressions 68 are formed at the upper end of the leg and these are adapted to accommodate downwardly extending tabs 70 formed at the corner regions of the lenses. The cap 66 generally comprises a shaft 72 and a head 74. The shaft 72 is provided with tangs 76 which resist, but do not prevent, the removal of the cap from engagement of the cap with an opening in the upper end of the leg. When four lenses 39 are connected around a leg, the concave corner regions of each lens ensure that a sufficient opening is left for the engagement of the cap with the leg. The diametrically larger head 74 of the cap bears on the upper surface of the lenses and prevents their vertical removal. Dependent from the periphery of the underside of the head region 74 are flanges 78. These engage in slots 80 formed on the upper surface of the lenses. The engagement of these, as well as the engagement of the tabs 70 with the depression 68, prevents any lateral movement of the lenses.

Each lens is held at all four corners so all lenses are securely mounted. FIGS. 7 and 8 show a lens 39 mounted on four legs 37. The other legs and lenses have been omitted for clarity but all would be mounted equivalently. FIG. 7 also shows the keyway slots 58 formed through the base plate 40 to which the lower ends 60 of the legs attach.

FIG. 9 shows a slightly alternative embodiment in which a different embodiment of leg has been used. Like parts have been given like reference numerals. In this embodiment leg 100 functions in a broadly equivalent way to the leg previously described in that it attaches by a twist-locking mechanism to the base place and has a cap which attaches to the upper end to hold lenses in place. The distinction in this embodiment is that the leg 100 and cap 102 are provided with a mechanism for the cleaning of both the photovoltaic cells 36 and the lenses 39.

Instead of being formed from fins, the legs 100 have a more tubular shape and pipes (not visible) are formed therein which connect to a source of cleaning fluid that is fed in from beneath the base plate 35. Upwardly and downwardly directed spray nozzles 104 are formed at various places on all the legs and caps 102. Conveniently a ring of four 90° degree separated nozzles are formed about half way up the leg and are downwardly directed toward the cells 36. Above these a ring of twelve equally spaced upwardly directed nozzles aim at the inside face of the lenses. Finally a similar ring of twelve nozzles is provided on the cap 102 to direct fluid down onto the outer faces of the lenses. When a pressurised cleaning fluid, such as water or compressed air, is introduced to the system this is discharged through the spray nozzles 104 and is directed onto the photovoltaic cells, the inside surfaces of the lenses and the outside surfaces of the lenses. FIG. 10 shows the spray patterns (numbered 106) achieved by the arrangement of nozzles depicted in FIG. 9. As can be seen, the downward spray onto the photovoltaic cells is concentrated onto those rather than onto the panel generally. The overlapping spray from several legs achieves an appropriate coverage and distribution of cleaning fluid to ensure adequate cleaning.

The cleaning fluid may be compressed air adapted to blow dirt from the relevant areas. Alternatively it may be a liquid such as water which is adapted to wash the relevant areas. Cleaning might be achieved by a combination of the two.

Although not shown, the pipes within the legs or in other places, could be connected to a single input port such that all nozzles within a sub-panel, or indeed several sub-panels, could be simultaneously operated by connection to a single source of cleaning fluid.

FIG. 11 shows the tracking assembly in more detail. The panel (comprising the framework of vertical and horizontal beams and attached sub-panels) is pivotally connected to the vertical member of the sub-frame about a generally vertical axis, such that it may rotate to track the horizontal movement of the sun. The sub-frame and attached panel may pivot about its connection to the support pillar in order to cause vertical tracking of the panel.

The movement of the solar panel with respect to the support pillar is controlled by various actuators. The sub-frame comprises a vertical member 29 and a horizontal member 30. A bracing plate 114 is connected across the union between the vertical member and the horizontal member to provide strength and also a pivot point for the connection to the upper end of the support pillar 16.

A generally triangular crank plate is pivotally connected at a first corner 117 to the horizontal member 113. A first end 119 of a first linear actuator 118 is pivotally connected to a second corner 120 of the crank plate 116. The first end of the first linear actuator 118 is the outer end of a reciprocating drive piston 122 which is capable of sliding backwards and forwards into a piston housing 124 under the control of a motor assembly 125. The drive piston, piston housing and motor assembly together comprise the actuator. The piston housing of the first linear actuator 118 is pivotally connected to the end of the horizontal member 30.

An equivalent second linear actuator 128 is pivotally connected to a third corner 130 of the crank plate 116. The outer end of the piston of the second linear actuator (which end is equivalent to the first end 119) is pivotally connected to the panel at bracket 131.

A third linear actuator 134 is pivotally connected to the vertical member 29 and the support pillar 26. The first, second and third linear actuators are all equivalent.

Horizontal tracking of the panel is achieved by rotation of that panel with respect to the pillar 26 and vertical member 29. Operation of the first and second linear actuators 118 and 128 achieves this movement. In FIGS. 1, 2 and 11 the panel is shown at approximately the middle of its range of movement. In practice in this configuration the panel would be directed towards the midday sun. To move the panel in the direction of arrow A (shown in FIG. 11) the first linear actuator would remain fixed but the second linear actuator would extend. Specifically the motor assembly would be operated to move its drive piston from within the piston housing thereby lengthening overall the actuator 128. This would force the panel to rotate with respect to the vertical member 112. Return movement back to the centre position could be accommodated by the contraction of the piston of the second linear actuator and or the contraction of the first linear actuator 118. Movement in the direction of arrow B would be achieved by the contraction of the first linear actuator 118. As the overall length of the first linear actuator 118 diminished as a result of the drive piston 122 sliding into the piston housing 124, the crank plate 116 would be forced to rotate in the direction of arrow C around the pivoting connection at the first corner 117 thereof. This would move the position of the third corner 130 and hence pull the panel by the second linear actuator to swing in the direction of arrow B.

Each piston housing is connected by means that allow appropriate rotation but not sliding. This can conveniently be achieved by a tight clasp around the housing that is mounted in a rotatable fashion to the lateral member, crank or other part.

FIG. 12 shows a plan view of a lens 39 depicting the surface facets. The lens generally has a smooth outer surface and a contoured inner face. In this embodiment each lens is approximately 160 mm square and has a maximum front-to-back thickness of 6 mm and a minimum of about 1.7 mm. The central region of 157×157 mm is divided into 121 square tiles of approximately 14.27 mm square. Each of these directs light onto a photovoltaic cell of approximately 16 mm square. The slightly smaller lens tiles, as compared to the size of the cells, improve alignment tolerance.

The lens may be injection-moulded from an acrylic material. The lens has a focal length of approximately 200 mm and consequently the mounting assembly holds the lenses approximately 200 mm above the upper surface of the panel.

Each tile within the lens is sub-divided into smaller prisms to ensure the minimum and maximum thicknesses are met. In this particular embodiment the total number of prisms is 813 with 31 different shapes. Clearly for a lens adapted to focus at a different focal length or of a different overall shape, or adapted to focus onto a different photovoltaic cell, an alternative design would be required.

FIG. 13 shows a schematic representation of a slightly different embodiment of panel. In this an aluminium base plate 210 has four carrier strips 212 bonded to its upper surface 214. Each carrier strip has three photovoltaic cells 216 which are interconnected by wires 218. When the upper surface 214 is directed toward the sun, light falling on the cells 216 causes a direct current to be generated in the wires 218—which wires are linked to a common output 220.

Each strip 212 comprises an elongate web 222 to which the cells 216 and wires 218 are attached. This may be either on the upper or lower face of the web, so that after connection to the base plate 210 they may be between the web 222 and plate 210 or on top of the web 222. Placing them between the web 222 and plate 210 ensures protection and good thermal coupling to the base plate 210. A protective sheet (not shown) may also be placed over some or all of the base plate and strips.

Manufacture of the panel may be achieved by laminating the strips (when suitably aligned) onto the base plate. This may be achieved sequentially or at the same time as application of a protective layer. The protective layer may be plastic, glass or other translucent material.

1. A solar energy assembly for collecting and converting solar energy comprising a plurality of solar energy converters and an equivalent number of solar concentrator lenses, each lens being associated with one energy converter and being adapted to concentrate light onto that energy converter.

2. A solar energy assembly as claimed in claim 1, wherein the lenses are separate from each other and may be mounted and replaced independently of the others.

3. A solar energy assembly as claimed in claim 1 in which a lens mounting system is provided to mount the lenses the correct focal distance above the energy converters.

4. A solar energy assembly as claimed in claim 1, wherein the solar energy converters are provided on a panel and the lenses are mounted above that panel.

5. A solar energy assembly as claimed in claim 4 comprising: one or more panel mounted on a support frame, each panel having a plurality of solar energy converters; a lens array adapted to focus light on to the solar energy converters; and a lens mounting system adapted to hold the lens array the desired focal distance from the solar energy converters.

6. A solar energy assembly as claimed in claim 5 wherein the support frame is pivotally connected to a mounting so that the solar energy converters and associated lens array may track the movement of the sun.

7. A solar energy assembly as claimed in claim 6 wherein a there is provided a tracking assembly to move the support frame relative to the mounting, the tracking assembly causing movement about two generally perpendicular axes of rotation and the tracking assembly comprised a crank, a first linear actuator connected to the mounting and the crank and a second linear actuator connected to the crank and the support frame, whereby linear extension of one or both actuators causes pivoting movement of the panel relative to the mounting assembly.

8. (canceled)

9. (canceled)

10. A solar energy assembly as claimed in claim 4, wherein a plurality of panels are attached side by side to form a composite panel.

11. A solar energy assembly as claimed in claim 1, wherein vents are provided to allow air to pass through or between the panel and the lens array.

12. A solar energy assembly as claimed in claim 11, wherein the vents are provided by one or more of spaces between adjacent panels, openings in the lens array, and/or openings in the mounting system.

13. A solar energy assembly as claimed in claim 1, wherein a cleaning system is provided to clean the solar energy converters and/or lenses.

14. A solar energy assembly as claimed in claim 13, wherein the cleaning system is incorporated in a mounting system for the lenses.

15. A solar energy assembly as claimed in claim 14, wherein the mounting system includes legs that extend between the panels and the lens array, and the cleaning system includes one or more spray nozzle on said legs.

16. A solar energy assembly as claimed in claim 15, wherein each leg has multiple nozzles to direct fluid upward onto the lens array and downwards onto the panel.

17. A solar energy assembly as claimed in claim 13, wherein the cleaning system is also adapted to direct fluid onto an external face of the lens array.

18. A solar energy assembly as claimed in claim 1, wherein there is further provided a lens mounting system adapted to hold an array comprising the lenses the desired focal distance from the solar energy converters.

19. A solar energy assembly as claimed in claim 18 wherein the mounting system comprising a plurality of legs that connect to the panels and to the lens array.

20. A solar energy assembly as claimed in claim 19, wherein the lenses are polygonal and tessellate, and the legs are adapted to connect to the corners of adjacent lenses.

21. A solar energy assembly as claimed in claim 20, wherein the lenses are generally rectangular and each leg is adapted to support four corners one from each of four adjacent lenses.

22. A solar energy assembly as claimed in claim 19, wherein the upper end of each leg is provided with releasable interlocking means that cooperate with formations on the lenses to hold the lenses in place.

23. A solar energy assembly as claimed in claim 22, wherein the upper end of each leg has 4 recesses; the corner of each lens has a tab that locates into a recess; and a cap is attached to the upper end of the leg to prevent removal of the tabs from the recesses.

24. A solar energy assembly as claimed in claim 4, wherein side walls are provided around the periphery of the panel, or composite panel, between the panel or composite panel and the lens array.

25. A solar energy assembly as claimed in claim 24, wherein the side walls connect to legs supporting the lens array adjacent the edge of the panel.

26. A solar energy assembly as claimed in claim 4 wherein each panel comprises a base sheet formed from a material of high thermal conductivity and a carrier strip having photovoltaic cells spaced therealong, the carrier strip being bonded to the base sheet which provides both mechanical support and a heat sink for the photovoltaic cells.

27. A solar energy assembly as claimed in claim 26, wherein a plurality of strips is provided across each base sheet.

28. A solar energy assembly as claimed in claim 27, wherein the strips are substantially parallel to each other and preferably arranged horizontally in use.

29. A solar energy assembly as claimed in claim 26, wherein the base sheet is formed from metal.

30. A solar energy assembly as claimed in claim 1, wherein the solar energy converters are photovoltaic cells.

31. A solar energy assembly as claimed in claim 1, wherein the lenses are Fresnel lenses.

32. A solar energy assembly as claimed in claim 1, wherein the desired focal distance between a lens and the associated solar energy converter is within the range of 18 to 22 cm.

33. A solar energy assembly for collecting and converting solar energy, comprising: a mounting; a support frame mounted on the mounting; a solar panel formed from a plurality of discrete sub-panels, attached side by side to the support frame each sub-panel having a plurality of solar energy converters; a lens array adapted to focus light on to the solar energy converters; and a lens mounting system adapted to hold the lens array the desired focal distance from the solar energy converters.
